(19) United States
(12) Patent Application Publication
(10) Pub. No.: US 2006/0012429 A1
(43) Pub. Date: Jan. 19, 2006

(54) Self biased differential amplifier

(75) Inventor: Ji-Hyun Kim, Gwacheon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/030,255

(22) Filed: Jan. 6, 2005

(30) Foreign Application Priority Data
Jul. 9, 2004 (KR) 04-53310

(51) Int. Cl. H03F 3/45

(52) U.S. Cl. 330/253

(57) ABSTRACT

A differential amplifier has an upper/lower and a left/right symmetric structure. The differential amplifier improves output voltage swings and gain without the need for additional circuits for driving current sources or voltage sources. The differential amplifier includes a first current source, a second current source, a first inverter, a second inverter and a self bias control circuit. The first current source and the second current source provide a first bias current and a second bias current. The self bias control circuit maintains the first bias current and the second bias current at a constant level. Therefore, the differential amplifier provides constant current without additional circuits for driving current sources or voltage sources, and achieves a wider range of voltage output swings and a higher gain, as compared to conventional differential amplifier configurations.

### RELATED APPLICATIONS

This application claims priority to Korean Patent Application No. 2004-53310, filed Jul. 9, 2004 in the Korean Intellectual Property Office (KIPO), the entire contents of which are incorporated herein by reference.

### BACKGROUND OF THE INVENTION

1. Field of the Invention

The present invention relates in general to a differential amplifier, and more specifically, to a self-biased differential amplifier.

2. Description of the Related Art

A differential amplifier is a circuit that is commonly employed for amplifying an input signal. Such amplifiers enjoy widespread use in many applications, for example as an input buffer or a receiver. The differential amplifier is commonly used as a receiving stage for a signal channel used for transferring signals between integrated circuits, or chips.

The differential amplifier receives first and second input signals via two complementary input terminals to generate output signals at two complementary output terminals. In this manner, differential amplifiers can achieve a wide range of output voltage swing and high gain, and may be employed to reduce common mode noise.

FIG. 1 is a circuit diagram of a conventional differential amplifier.

Referring to FIG. 1, the differential amplifier includes two input transistors M1 and M2 for receiving differential input signals, an active load comprising a current mirror, and a current source Iss for providing a constant current to the differential amplifier. The differential amplifier illustrated in FIG. 1, amplifies the differential input signals that are received via input terminals IN and INB and outputs amplified signals to output terminals OUT and OUTB. Hereinafter, a small-signal gain of the differential amplifier of FIG. 1 will be described.

Generally, a small-signal gain of an amplifier is expressed as a product of a small-signal trasconductance and a small-signal output resistance of the amplifier. Thus, the gain of the differential amplifier measured at one output terminal OUT of the differential amplifier of FIG. 1 is expressed as in Expression 1. In Expression 1, gm₂ represents a small-signal transconductance of the input transistor M2, and r₂ and r₄ are small-signal output resistances of the input transistor M2 and the transistor M4 connected to the output terminal OUT, respectively.

$$Av = \frac{Vout}{Vin} = {gm}_{2} ( {r}_{2} ‖ {r}_{4} ) \qquad < Expression 1 >$$

The gain Av in Expression 1 represents the gain measured at the output terminal OUT of the differential amplifier illustrated in FIG. 1. When the input signals are applied to the input terminals IN and INB, the voltage of the output terminal OUTB changes as well. However, the voltage change at the output terminal OUTB is small because the transistor M3 connected to the output terminal OUTB has a diode connection configuration. Therefore, the differential amplifier illustrated in FIG. 1 has a gain Av as expressed in Expression 1.

The differential amplifier illustrated in FIG. 1 has limited output swing due to the current source and the active load, and requires additional circuits for driving the current source so as to provide a constant current to the differential amplifier circuit. Thus, the differential amplifier illustrated in FIG. 1 consumes additional current because of the additional circuits. In addition, the limitation of output swings and imbalance between the voltages at two output terminals OUT and OUTB, reduce noise margin in the circuit.

A CMOS differential amplifier is disclosed in Korean Patent Laid-Open Publication No. 2000-0009114, entitled “DIFFERENTIALAMPLIFIER”. The CMOS differential amplifier obtains a high gain by receiving an input signal through a structure of a CMOS inverter, and does not require additional circuits for driving a current source or a voltage source. However, the above-described CMOS differential amplifier is not able to provide a constant bias current.

FIG. 2 is a circuit diagram of a conventional CMOS differential amplifier of the type disclosed in Korean Patent Laid-Open Publication No. 2000-0009114.

As shown in FIG. 2, the CMOS differential amplifier includes first and second differential amplifying sections 11 and 21, first and second high voltage bias sections 12 and 22, and first and second low voltage bias sections 13 and 23. The first and second differential amplifying sections 11 and 21 amplify differential input signals Vp and Vn via the CMOS inverters 14 and 15, and the CMOS inverters 24 and 25, respectively. The first and second high voltage bias sections 12 and 22 provide a high bias voltage according to the output of the first and second differential amplifying sections 11 and 21. The first and second low voltage bias sections 13 and 23 provide a low bias voltage according to the output of the first and second differential amplifying sections 11 and 21.

In the CMOS differential amplifier illustrated in FIG. 2, when the input voltage Vp increases by a small voltage level and the input voltage Vn decreases by a small voltage level (when complementary small signals are applied to the input terminals), the bias current in the first high voltage bias section 12 increases and the bias current in the first low voltage bias section 13 decreases, because the voltage of a node N10 decreases as a result of the increase of the voltage of the input signal Vp.

Similarly, the bias current in the second high voltage bias section 22 decreases and the bias current in the second low voltage bias section 23 increases, because the voltage of a node N20 increases as a result of the decrease of the voltage of the input signal Vn.

On the other hand, when the input voltage Vp decreases by the small voltage level and the input voltage Vn increases by the small voltage level, the bias current in the first high voltage bias section 12 decreases and the bias current in the first low voltage bias section 13 increases, because the voltage of a node N10 increases as a result of the decrease of the voltage of the input signal Vp.

Similarly, the bias current in the second high voltage bias section 22 increases and the bias current in the second low voltage bias section 23 decreases because the voltage of the node N20 decreases as a result of the increase of the voltage of the input signal Vn.

Consequently, the CMOS differential amplifier illustrated in FIG. 2 has a mismatch of bias currents of the high voltage/low voltage and first/second bias sections, when the differential small signals are input thereto. This mismatch of the bias currents has an adverse effect on the gain, the output swing range, and the frequency characteristics of the differential amplifier, leading to a decrease in amplifier performance.

### SUMMARY OF THE INVENTION

Accordingly, the present invention is provided to substantially obviate one or more problems due to the above-described limitations and disadvantages of the related art.

It is a feature of the present invention to provide a differential amplifier capable of providing substantially constant bias current without the need for additional circuits for driving current sources or voltage sources.

In one embodiment, the present invention is directed to a differential amplifier. The amplifier includes a first current source, coupled between a first power voltage and a first node, and configured to provide a first bias current in response to a control signal and an inverted control signal. A second current source is coupled between a second power voltage and a second node, and is configured to provide a second bias current in response to the control signal and the inverted control signal. A first inverter is coupled between the first node and the second node, and is configured to amplify an input signal to generate an inverted output signal. A second inverter is coupled between the first node and the second node, and is configured to amplify an inverted input signal to generate an output signal. A self bias control circuit is coupled between the first node and the second node, and is configured to generate the control signal and the inverted control signal to control the first bias current and the second bias current in response to the input signal and the inverted input signal.

In one embodiment, the self bias control circuit comprises: a third inverter configured to amplify the input signal to generate the inverted control signal; and a fourth inverter configured to amplify the inverted input signal to generate the control signal. The first, second, third and fourth inverters comprise CMOS inverters in which a first PMOS transistor and a first NMOS transistor are serially coupled to each other.

In one embodiment, the first current source comprises: a first sub current source, coupled between the first power voltage and the first node, configured to provide a first sub-bias current to the first node in response to the inverted control signal; and a second sub current source, coupled between the first power voltage and the first node, configured to provide a second sub-bias current to the first node in response to the control signal, the second sub-bias current being controlled complementarily with respect to the first sub-bias current, and wherein the first current source adds the first sub-bias current and the second sub-bias current to generate the first bias current.

In one embodiment, the second current source comprises: a first sub current sink, coupled between the second power voltage and the second node, configured to provide a third sub-bias current to the second node in response to the inverted control signal; and a second sub current sink coupled between the second power voltage and the second node configured to provide a fourth sub-bias current to the second node in response to the control signal, the fourth sub-bias current being controlled complementary with respect to the third sub-bias current, and wherein the second current source adds the third sub-bias current and the fourth sub-bias current to generate the second bias current.

In one embodiment, the first sub-bias current increases when the fourth sub-bias current increases, the first sub-bias current decreases when the fourth sub-bias current decreases, the second sub-bias current increases when the third sub-bias current increases and the second sub-bias current decreases when the third sub-bias current decreases.

In one embodiment, the amount of the first bias current is the same as that of the second bias current. The first sub current source and the second sub current source include second PMOS transistors respectively, and the first sub current sink and the second sub current sink include second NMOS transistors respectively. The second PMOS transistors and the second NMOS transistors operate in a linear region.

In one embodiment, the first power voltage is about 1.8 volts and the second power voltage is about 0 volt. The input signal and the inverted input signal include small-signals biased at about 0.9 volts.

According to above exemplary embodiment of the present invention, constant self-bias current is achieved without the need for using additional circuits for driving current sources or voltage sources. Moreover, high gain and wide range of output swings are achieved.

### BRIEF DESCRIPTION OF THE DRAWINGS

The above and other features and advantages of the present invention will become more apparent by describing in detail exemplary embodiment thereof with reference to the accompanying drawings, in which:

FIG. 1 is a circuit diagram illustrating a conventional differential amplifier;

FIG. 2 is a circuit diagram illustrating another conventional differential amplifier;

FIG. 3 is a circuit diagram illustrating a differential amplifier in accordance with one exemplary embodiment of the present invention;

FIG. 4 is a circuit diagram illustrating a CMOS inverter corresponding to the inverters of the differential amplifier of FIG. 3;

FIG. 5 is a circuit diagram illustrating a small-signal equivalent circuit model of the CMOS inverter of FIG. 4;

FIG. 6A is a graph illustrating simulation waveforms in which input swing range of the differential amplifier of FIG. 1 is about 0.4 volt;

FIG. 6B is a graph illustrating simulation waveforms in which input swing range of the differential amplifier of FIG. 3 is about 0.4 volt;

FIG. 7A is a graph illustrating simulation waveforms in which input swing range of the differential amplifier of FIG. 1 is about 0.04 volt;

FIG. 7B is a graph illustrating simulation waveforms in which input swing range of the differential amplifier of FIG. 3 is about 0.04 volt;

FIG. 8A is a graph illustrating simulation waveforms in which input swing range of the differential amplifier of FIG. 1 is about 0.004 volt; and

FIG. 8B is a graph illustrating simulation waveforms in which input swing range of the differential amplifier of FIG. 3 is about 0.004 volt.

### DETAILED DESCRIPTION OF PREFERRED EMBODIMENTS

Detailed illustrative embodiments of the present invention are disclosed herein. However, specific structural and functional details disclosed herein are merely representative for purposes of describing exemplary embodiments of the present invention. This invention may be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the present invention covers all modifications, equivalents, and alternatives falling within the spirit and scope of the invention. Like numbers refer to like elements throughout the description of the figures.

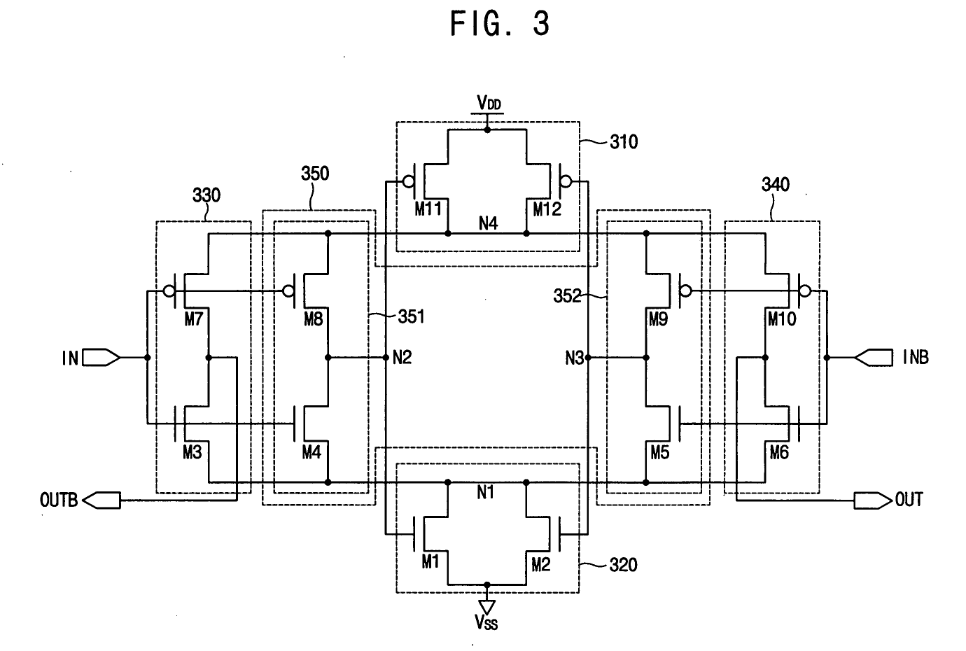

FIG. 3 is a circuit diagram illustrating a differential amplifier in accordance with one exemplary embodiment of the present invention.

As shown in FIG. 3, the differential amplifier in accordance with one exemplary embodiment of the present invention includes a first current source 310, a second current source 320, a first inverter 330, a second inverter 340, and a self-bias control circuit 350. The self-bias control circuit 350 includes a third inverter 351 and a fourth inverter 352.

The first current source 310 includes a pair of PMOS transistors M11 and M12 connected between a first power voltage VDD and a first node N4. The second current source 320 includes a pair of NMOS transistors M1 and M2 coupled between a second power voltage Vss and a second node N1.

The first inverter 330 includes PMOS transistor M7 and NMOS transistor M3. The PMOS transistor M7 and the NMOS transistor M3 are serially connected between the first node N4 and the second node N1. The first inverter 330 amplifies an input signal input via an input terminal IN to generate an inverted output signal output to an inverted output terminal OUTB. The second inverter 340 includes PMOS transistor M10 and NMOS transistor M6. The PMOS transistor M11 and the NMOS transistor M6 are serially connected between the first node N4 and the second node N1. The second inverter 340 amplifies an inverted input signal input via an inverted input terminal INB to generate an output signal output to an output terminal OUT.

The self-bias control circuit 350 is connected between the first node N4 and the second node N1, and generates a control signal and an inverted control signal. The control signal and the inverted control signal are provided to the first current source 310 and the second current source 320 via a third node N2 and a fourth node N3.

The self-bias control circuit 350 includes a third inverter 351 and a fourth inverter 352. The third inverter 351 generates the inverted control signal to control the first current source 310 and the second current source 320 via the third node N2. The fourth inverter 352 generates the control signal to control the first current source 310 and the second current source 320 via the fourth node N4.

The third inverter 351 includes PMOS transistor M8 and NMOS transistor M4. The PMOS transistor M8 and the NMOS transistor M4 are serially connected between the first node N4 and the second node N1. The third inverter 351 amplifies the input signal input via the input terminal IN to generate an inverted control signal. The inverted control signal is output to the first current source 310 and the second current source 320 via the third node N2.

The fourth inverter 352 includes PMOS transistor M9 and NMOS transistor M5. The PMOS transistor M9 and the NMOS transistor M5 are serially connected between the first node N4 and the second node N1. The fourth inverter 352 amplifies the inverted input signal input via the inverted input terminal INB to generate a control signal. The control signal is output to the first current source 310 and the second current source 320 via the fourth node N3.

The inverted control signal is input to the gate of the PMOS transistor M11 of the first current source 310 and the gate of the NMOS transistor M1 of the second current source 320. The control signal is input to the gate of the PMOS transistor M12 of the first current source 310 and the gate of the NMOS transistor M2 of the second current source 320.

The differential amplifier illustrated in FIG. 3 provides a constant bias current without using additional circuits for driving current sources. Hereinafter, the operation of the differential amplifier illustrated in FIG. 3 will be described in detail.

When an input voltage (i.e. small-signal voltage) applied to the input terminal IN increases and another input voltage (i.e. small-signal voltage) applied to the input terminal INB decreases, the current flowing through the PMOS transistor M8 of the third inverter 351 decreases and the current flowing through the NMOS transistor M4 of the third inverter 351 increases, so that the voltage of the third node N2 decreases. Therefore, the current flowing through the PMOS transistor M11 of the first current source 310 increases, and the current flowing through the NMOS transistor M1 of the second current source 320 decreases.

Concurrently, the current flowing through the PMOS transistor M9 of the fourth inverter 352 increases and the current flowing through the NMOS transistor M5 of the fourth inverter 352 decreases so that the voltage of the fourth node N3 increases. Therefore, the current flowing through the PMOS transistor M12 of the first current source 310 decreases, and the current flowing through the NMOS transistor M2 of the second current source 320 increases.

On the other hand, when the input voltage applied to one input terminal IN decreases and the input voltage applied to the other input terminal INB increases, the current flowing through the PMOS transistor M8 of the third inverter 351 increases and the current flowing through the NMOS transistor M4 of the third inverter 351 decreases so that the voltage of the third node N2 increases. Therefore, the current flowing through the PMOS transistor M11 of the first current source 310 decreases, and the current flowing through the NMOS transistor M1 of the second current source 320 increases.

Concurrently, the current flowing through the PMOS transistor M9 of the fourth inverter 352 decreases and the current flowing through the NMOS transistor M5 of the fourth inverter 352 increases, so that the voltage of the fourth node N3 decreases. Therefore, the current flowing through the PMOS transistor M12 of the first current source 310 increases, and the current flowing through the NMOS transistor M2 of the second current source 320 decreases.

As a result, the PMOS transistors M11 and M12 of the first current source 310 operate in complementary fashion with respect to each other to provide constant current, and the NMOS transistor M1 and M2 of the second current source 320 operate in complementary fashion with respect to each other to provide constant current as well. Moreover, the current through the PMOS transistor M11 increases when the current through the NMOS transistor M2 increases and the current through the PMOS transistor M11 decreases when the current through the NMOS transistor M2 decreases. The current through the PMOS transistor M12 increases when the current through the NMOS transistor M1 increases and the current through the PMOS transistor M12 decreases when the current through the NMOS transistor M1 decreases. Therefore, when the input signal and the inverted input signal are complementary small signals, the first bias current provided by the first current source 310 and the second bias current provided by the second current source 320 are maintained substantially constant.

Thus, in the amplifier circuit configuration of FIG. 3, there is no mismatch between the first bias current and the second bias current, and the first current source and the second current source operate as ideal current sources. When complementary small signals are applied to the input terminals IN and INB, the first current source 310 and the second current source 320 serve as ideal current sources without the need for additional circuits for driving the first current source 310 and the second current source 320.

The PMOS transistors M11 and M12 of the first current source 310 and the NMOS transistors M1 and M2 of the second current source 320 of FIG. 3 operate in a linear region of the devices. The first node N4 is maintained as the voltage level of about the first power voltage VDD, and the second node N1 is maintained as the voltage level of about the second power voltage Vss. Thus, the output signals at the output terminals OUT and OUTB may have a wider voltage swing range. The wide swing range of the output signals leads to a higher noise margin when the differential amplifier interfaces with other logic circuits.

Hereinafter, the gain of the first inverter 330 and the second inverter 340 of the differential amplifier illustrated in FIG. 3 is explained in detail. Both the first inverter 330 and the second inverter 340 have the structure of a CMOS inverter. Hereinafter, for example, the operation and gain of the first inverter 330 is explained.

FIG. 4 is a circuit diagram illustrating a CMOS inverter corresponding to the inverters of the differential amplifier of FIG. 3.

The CMOS inverter of FIG. 4 is identical to the first inverter 330 of FIG. 3 except that a PMOS transistor MP is connected directly to the first power voltage VDD and an NMOS transistor MN is connected directly to the second power voltage Vss. Instead, the transistors of the first inverter of FIG. 3 are serially connected between the first node N4 and the second node N1. However, the voltage level of the first node N4 is substantially equal to the first power voltage VDD and the voltage level of the second node N1 is substantially equal to the second power voltage Vss when small signal inputs are applied to the differential amplifier of FIG. 3. Thus, hereinafter, the small-signal gain of the CMOS inverter of FIG. 4 will be described.

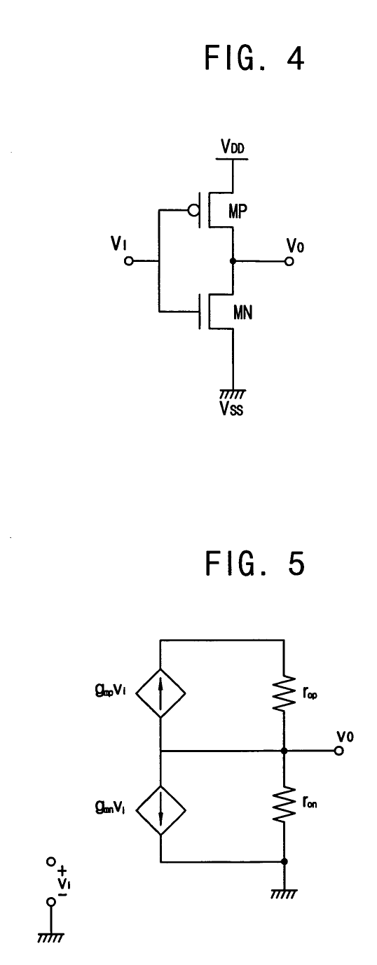

FIG. 5 is a circuit diagram illustrating a small-signal equivalent circuit model of the CMOS inverter of FIG. 4.

Referring to FIG. 5, gmp and gmn represent transconductances of the PMOS transistor MP and the NMOS transistor MN, respectively, and rop and ron are small-signal output resistances of the PMOS transistor MP and the NMOS transistor MN, respectively. In FIG. 5, vi and vo are the small-signal components of the input voltage Vi and the output voltage Vo of FIG. 4, respectively. Referring to FIG. 5, the small-signal gain of the CMOS inverter illustrated in FIG. 4, may be calculated as represented in Expression 2.

$$\frac{vo}{vi} = - ( {g}_{mn} + {g}_{mp} ) ( {r}_{on} ‖ {r}_{op} ) \qquad < Expression 2 >$$

The small-signal gain of the first inverter 330 illustrated in FIG. 3 is calculated as represented in Expression 2, and the small-signal gain of the second inverter 340 is identical to the gain of the first inverter 330 because the structure of the first inverter 330 are identical to that of the second inverter 340. Therefore, the differential amplifier illustrated in FIG. 3 has almost the same gain as the gain described in Expression 2.

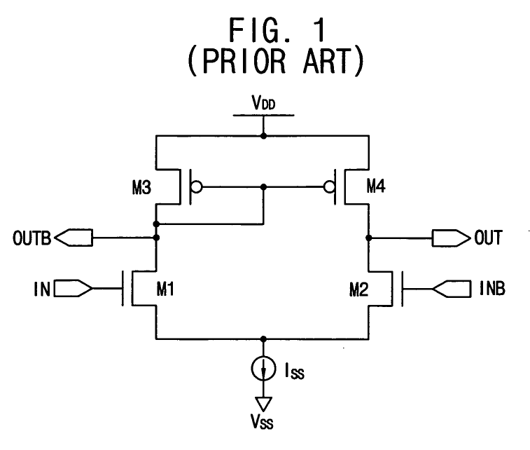

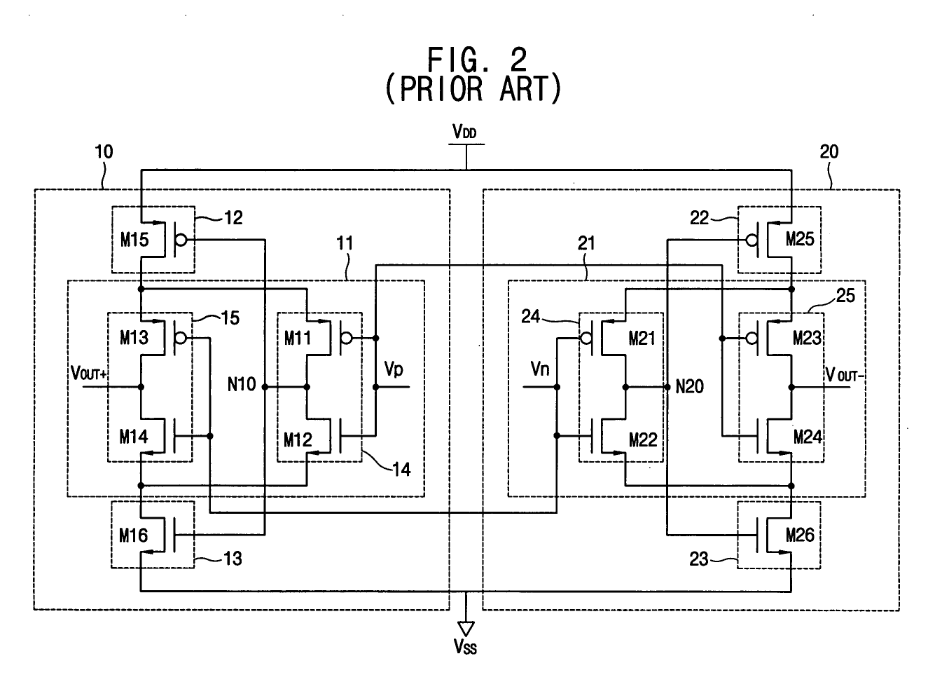

The differential amplifier of FIG. 3 has a gain that is about two times that of the differential amplifier of FIG. 1.

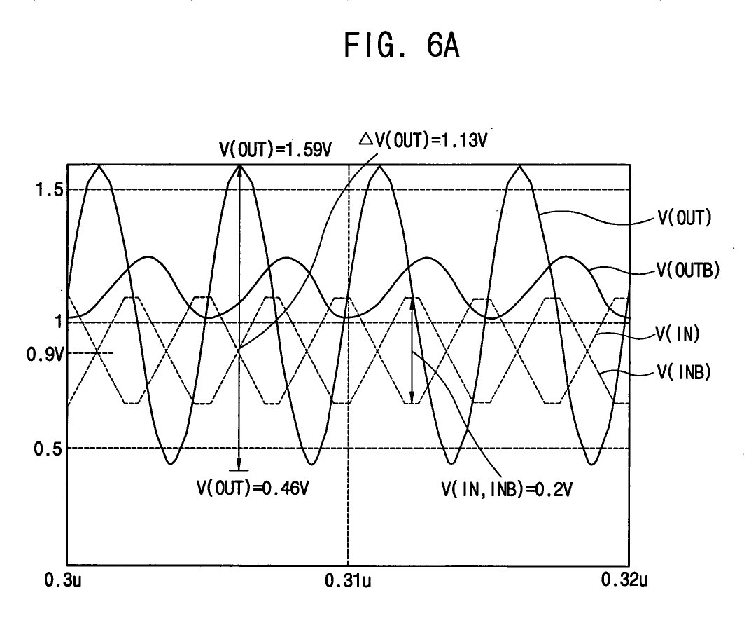

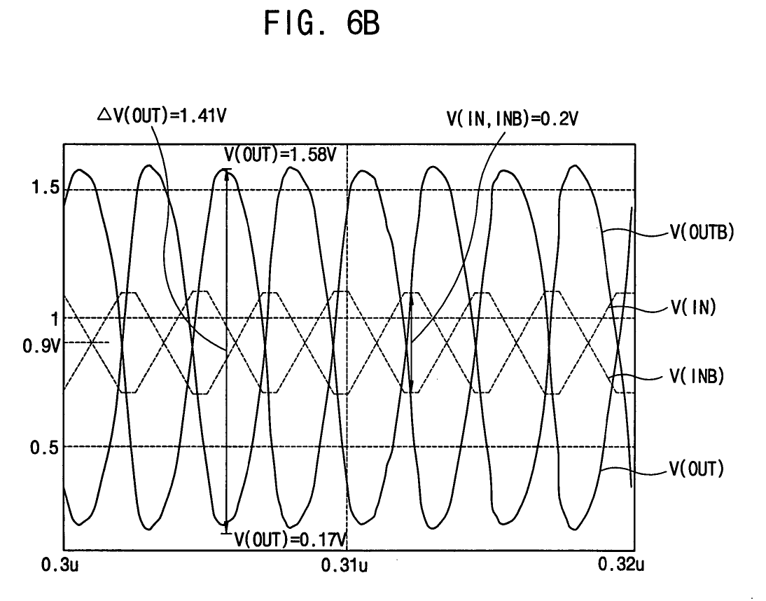

FIG. 6A is a graph illustrating simulation waveforms of input/output signals in which the input swing range of the differential amplifier of FIG. 1 is about 0.4 volt.

The simulation waveform of FIG. 6A is a simulation result when the first power voltage VDD is about 1.8 volts, the second power voltage Vss is about 0 volt, the frequency of the input signals is about 200 MHz, and the input signals have a swing range between about 0.7 volt and about 1.1 volts. In other words, the input signals swing in a width of about 0.2 volt with respect to about 0.9 volt. Hereinafter, the input signals are represented as V (IN.INB)=0.2 volt. A signal V (OUT) represents the output signal from the output terminal OUT illustrated in FIG. 1. A signal V (OUTB) represents the output signal from the output terminal OUTB illustrated in FIG. 1. As shown in FIG. 1 and FIG. 6A, the swing range of the signal V (OUT) is limited by the current source Iss and the transistor M2 or the current source Iss and the transistor M1. The swing range of the signal V (OUTB) is narrower than that of the signal V (OUT) due to the diode connected transistor M3. In FIG. 6A, the signal V (OUT) swings in a range from about 0.46 volt to about 1.59 volts, and ΔV (OUT) is about 1.13 volt.

FIG. 6B is a graph illustrating simulation waveforms of input/output signals in which the input swing range of the differential amplifier of FIG. 3 is about 0.4 volt. The simulation waveform illustrated in FIG. 6B is a simulation result when the first power voltage VDD is about 1.8 volts, the second power voltage Vss is about 0 volt, the frequency of the input signals V (IN.INB) is about 200 MHz, and the input signal V (IN.INB) swings in a swing width of about 0.2 volt with respect to about 0.9 volt. A signal V (OUT) represents the output signal from the output terminal OUT of FIG. 3. A signal V (OUTB) represents the output signal from the output terminal OUTB of FIG. 3. As shown in FIG. 3 and FIG. 6B, the transistors M1, M2, M11 and M12 of the first current source 310 and the second current source 320 of FIG. 3, operate in a linear region so that the first node N4 and the second node N1 are maintained as the voltage about equal to the first power voltage VDD and the voltage about equal to the second power voltage Vss, respectively. Therefore, the output signals V (OUT) and V (OUTB) have full swing level and demonstrate symmetry with respect to each other. The output range ΔV (OUT) is about 1.41 volt.

In comparison of FIG. 6B with FIG. 6A, the differential amplifier of FIG. 3 has a higher gain, more symmetric output signals from the output terminals OUT and OUTB and wider swing range than the differential amplifier of FIG. 1. Moreover, the bias voltage of the output signal is closer to the bias voltage, i.e. about 0.9 volt, of the input signal in the differential amplifier of FIG. 3, as compared to the bias voltage of the differential amplifier of FIG. 1.

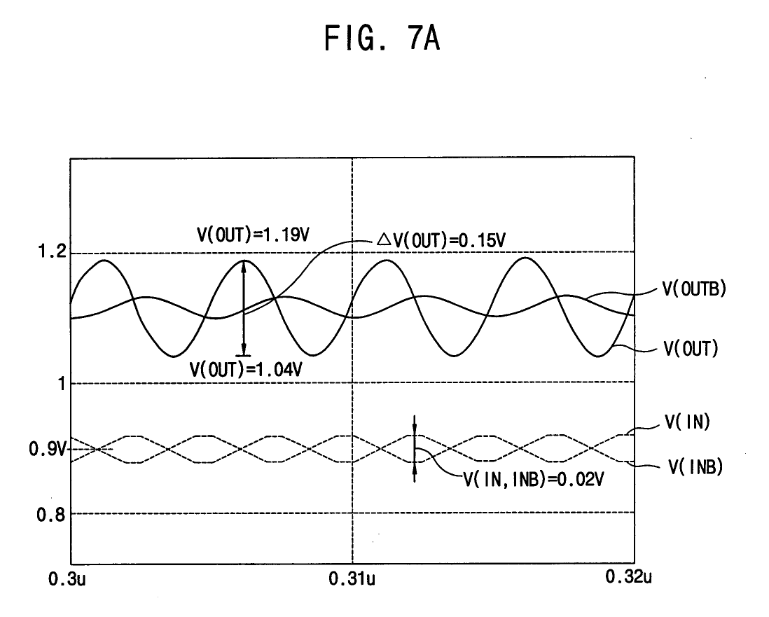

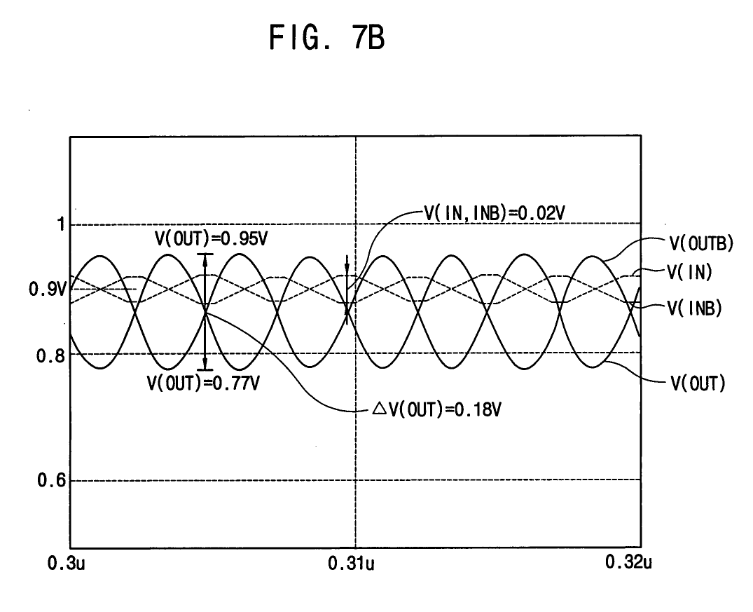

FIG. 7A is a graph illustrating simulation waveforms of input/output signals in which the input swing range of the differential amplifier of FIG. 1 is about 0.04 volt. As shown in FIG. 7A, the output range ΔV (OUT) is about 0.15 volt.

FIG. 7B is a graph illustrating simulation waveforms of input/output signals in which the input swing range of the differential amplifier of FIG. 3 is about 0.04 volt. As shown in FIG. 7B, the output range ΔV (OUT) is about 0.18 volt.

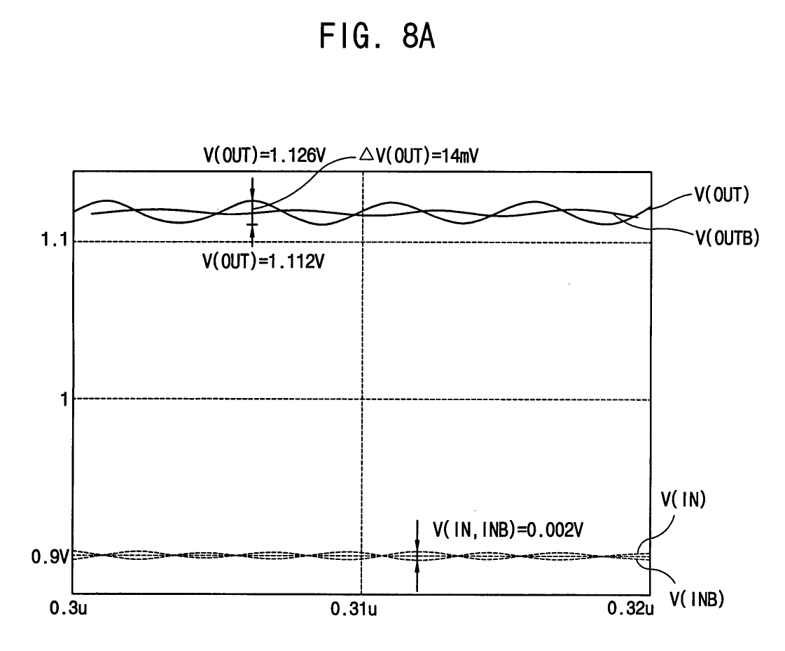

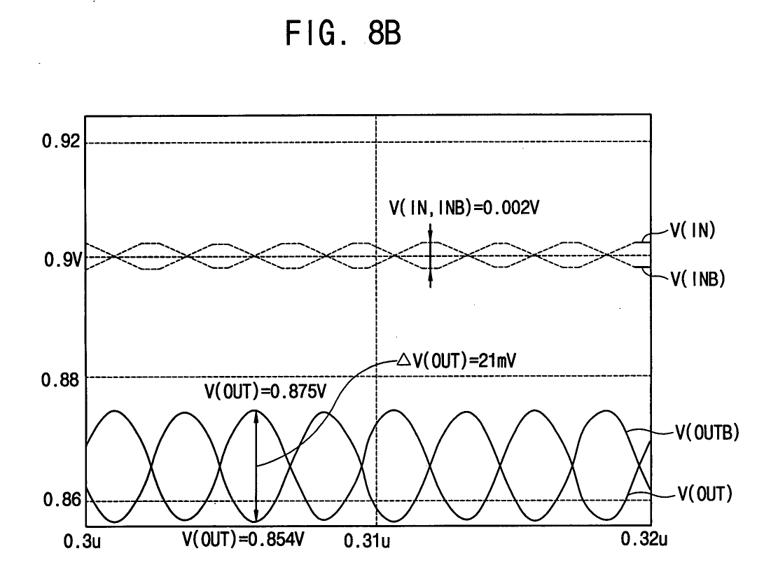

FIG. 8A is a graph illustrating simulation waveforms of input/output signals in which the input swing range of the differential amplifier of FIG. 1 is about 0.004 volt. As shown in FIG. 8A, the output range ΔV (OUT) is about 14 millivolts.

FIG. 8B is a graph illustrating simulation waveforms of input/output signals in which the input swing range of the differential amplifier of FIG. 3 is about 0.004 volt. As shown in FIG. 8B, the output range ΔV (OUT) is about 21 millivolts.

In conclusion, the simulation results of FIG. 6A through FIG. 8B demonstrate that the differential amplifier of FIG. 3 according to the exemplary embodiment of the present invention has a higher gain and a wider output swing range than the conventional differential amplifier of FIG. 1. Especially, referring to the simulation result of FIG. 8A and FIG. 8B, the differential amplifier according to the exemplary embodiment of the present invention has about two times higher gain than that of the conventional amplifier when the input signals have small swing range such as about 0.004 volt.

The differential amplifier according to the exemplary embodiment of the present invention provides a substantially constant bias current without the need for additional circuits for driving current sources when complementary small-signals are input thereto. The differential amplifier according to the exemplary embodiment of the present invention adopts the structure of CMOS inverter to achieve a high small signal gain.

The transistors of the first current source and the second current source operate in the linear region so that the differential amplifier according to the exemplary embodiment of the present invention achieves a wide range of output swing and high noise margin.

Moreover, the differential amplifier according to the exemplary embodiment of the present invention has an upper/lower and lefuright symmetric structure to achieve fully differential output and to have reduced distortion.

As mentioned above, the differential amplifier according to the exemplary embodiment of the present invention does not require additional circuits for driving current sources or voltage sources. In this manner, power consumption and circuit size are reduced.

While the exemplary embodiments of the present invention and their advantages have been described in detail, it should be understood that various changes, substitutions and alterations may be made herein without departing from the scope of the invention.

What is claimed is:

1. A differential amplifier comprising:
a first current source, coupled between a first power voltage and a first node, configured to provide a first bias current in response to a control signal and an inverted control signal;
a second current source, coupled between a second power voltage and a second node, configured to provide a second bias current in response to the control signal and the inverted control signal;
a first inverter, coupled between the first node and the second node, configured to amplify an input signal to generate an inverted output signal;
a second inverter, coupled between the first node and the second node, configured to amplify an inverted input signal to generate an output signal; and
a self bias control circuit, coupled between the first node and the second node, configured to generate the control signal and the inverted control signal to control the first bias current and the second bias current in response to the input signal and the inverted input signal.

2. The differential amplifier according to claim 1, wherein the self bias control circuit comprises:
a third inverter configured to amplify the input signal to generate the inverted control signal; and
a fourth inverter configured to amplify the inverted input signal to generate the control signal.

3. The differential amplifier according to claim 2, wherein the first, second, third and fourth inverters are CMOS inverters in which a first PMOS transistor and a first NMOS transistor are serially coupled to each other.

4. The differential amplifier according to claim 1, wherein the first current source comprises:
a first sub current source, coupled between the first power voltage and the first node, configured to provide a first sub-bias current to the first node in response to the inverted control signal; and
a second sub current source, coupled between the first power voltage and the first node, configured to provide a second sub-bias current to the first node in response to the control signal, the second sub-bias current being controlled complementarily with respect to the first sub-bias current, and wherein the first current source adds the first sub-bias current and the second sub-bias current to generate the first bias current.

5. The differential amplifier according to claim 4, wherein the second current source comprises: a first sub current sink, coupled between the second power voltage and the second node, configured to provide a third sub-bias current to the second node in response to the inverted control signal; and
a second sub current sink coupled between the second power voltage and the second node configured to provide a fourth sub-bias current to the second node in response to the control signal, the fourth sub-bias current being controlled complementary with respect to the third sub-bias current, and wherein the second current source adds the third sub-bias current and the fourth sub-bias current to generate the second bias current.

6. The differential amplifier according to claim 5, wherein the first sub-bias current increases when the fourth sub-bias current increases, the first sub-bias current decreases when the fourth sub-bias current decreases, the second sub-bias current increases when the third sub-bias current increases and the second sub-bias current decreases when the third sub-bias current decreases.

7. The differential amplifier according to claim 6, wherein an amount of the first bias current is the same as that of the second bias current.

8. The differential amplifier according to claim 5, wherein the first sub current source and the second sub current source include second PMOS transistors respectively, and the first sub current sink and the second sub current sink include second NMOS transistors respectively.

9. The differential amplifier according to claim 8, wherein the second PMOS transistors and the second NMOS transistors operate in a linear region.

10. The differential amplifier according to claim 1, wherein the first power voltage is about 1.8 volts and the second power voltage is about 0 volt.

11. The differential amplifier according to claim 1, wherein the input signal and the inverted input signal include small-signals biased at about 0.9 volts.
